(19) United States
(12) Patent Application Publication
(10) Pub. No.: US 2023/0393480 A1
(43) Pub. Date: Dec. 7, 2023

(54) MANUFACTURING METHOD OF FLEXOGRAPHIC PRINTING PLATE

(71) Applicant: FUJIFILM Corporation, Tokyo (JP)

(72) Inventor: Kenji KANO, Haibara-gun (JP)

(73) Assignee: FUJIFILMCorporation, Tokyo (JP)

(21) Appl. No.: 18/452,721

(22) Filed: Aug. 21, 2023

Related U.S. Application Data
(63) Continuation of application No. PCT/JP2022/006155, filed on Feb. 16, 2022.

(30) Foreign Application Priority Data
Feb. 26, 2021 (JP) 2021-030910

(51) Int. Cl. G03F 7/12; B41C 1/10

(52) U.S. Cl. CPC G03F 7/12; B41C 1/1008; B41C 2210/04

(57) ABSTRACT

Provided is a manufacturing method of a flexographic printing plate, which achieves both a depth of a concave portion and reproducibility of independent dots by eliminating an insufficient depth of the concave portion and increasing a cured region around the independent dots. The manufacturing method of a flexographic printing plate includes an exposure step of irradiating, with an energy ray, a flexographic printing plate precursor which includes, in the following order, at least a support, a photosensitive layer, and a mask portion on which an image is formed, through the mask portion to expose the photosensitive layer, and a development step of removing a non-exposed portion of the photosensitive layer. The exposure step includes a step of radiating the energy ray in a state in which, from the photosensitive layer side, the mask portion and a film-like optical element are present in this order between an energy source and the photosensitive layer. The film-like optical element is an element which converges the incident energy ray to enhance directivity and emits the energy ray to the mask portion.

### CROSS-REFERENCE TO RELATED APPLICATIONS

This application is a Continuation of PCT International Application No. PCT/JP2022/006155 filed on Feb. 16, 2022, which claims priority under 35 U.S.C. § 119(a) to Japanese Patent Application No. 2021-030910 filed on Feb. 26, 2021. The above applications are hereby expressly incorporated by reference, in their entirety, into the present application.

### BACKGROUND OF THE INVENTION

### 1. Field of the Invention

The present invention relates to a manufacturing method of a flexographic printing plate, in which a film-like optical element is used during exposure.

### 2. Description of the Related Art

Flexographic printing is a printing method in which an ink is applied to a convex portion of a printing plate using an anilox roll or the like, and is transferred to an object to be printed. As a flexographic printing plate used for the flexographic printing, for example, a flexographic printing plate precursor having a photosensitive layer, which has been exposed and developed imagewise, is used. Various methods have been known as a manufacturing method of the flexographic printing plate. For example, WO2019/130784A discloses a manufacturing method of a flexographic printing plate.

In WO2019/130784A, in order to form a relief image on a photosensitive layer of a flexographic printing plate precursor, ultraviolet irradiation is performed from a substrate side of the flexographic printing plate precursor (back exposure). Ultraviolet rays can be emitted from a high-pressure mercury lamp, an ultrahigh-pressure mercury lamp, a metal halide lamp, a xenon lamp, a carbon arc lamp, a chemical lamp, a light emitting diode (LED), or the like, which can perform irradiation with light having a wavelength of 300 to 400 nm.

In a case of using the analog type flexographic printing plate precursor, the protective film is peeled off, and the negative film on which an image is formed in advance is closely attached to the exposed anti-adhesion layer. On the other hand, in a case of using a laser ablation mask (LAM) type flexographic printing plate precursor, the protective film is peeled off, and a desired image is formed by, for example, irradiating the exposed infrared ablation layer with an infrared laser.

Next, the photosensitive layer is cured by irradiating ultraviolet rays from above the negative film or the infrared ablation layer (main exposure). An irradiated portion of the photosensitive layer is cured by irradiation with ultraviolet rays. The photosensitive layer covered with the negative film or the infrared ablation layer has a cured portion irradiated with ultraviolet rays and an uncured portion not irradiated with ultraviolet rays. Next, the relief image is formed by removing the uncured portion of the photosensitive layer in the developer. Next, the uncured portion is removed by taking out a printing plate material from the developer and drying the printing plate material, or by applying heat to closely attach to a nonwoven fabric and transferring the uncured portion to the nonwoven fabric. The entire printing plate material is irradiated with ultraviolet rays as necessary (post-exposure). In this manner, a flexographic printing plate is obtained.

### SUMMARY OF THE INVENTION

In the manufacturing method of a flexographic printing plate of WO2019/130784A, scattered light is used for the exposure of the flexographic printing plate precursor. In a case where the scattered light is used for the exposure, the photosensitive layer of the flexographic printing plate precursor is cured by halation, so that a depth of the concave portion is insufficient. In addition, in a case where collimated light is used for the exposure, a cured region around independent dots in the photosensitive layer is smaller and the independent dots tend to disappear during development, so that reproducibility of the independent dots of the flexographic printing plate is deteriorated.

An object of the present invention is to provide a manufacturing method of a flexographic printing plate, which achieves both a depth of a concave portion and reproducibility of independent dots by eliminating an insufficient depth of the concave portion and increasing a cured region around the independent dots.

In order to achieve the above-described object, one aspect of the present invention is to provide a manufacturing method of a flexographic printing plate, including an exposure step of irradiating, with an energy ray, a flexographic printing plate precursor which includes, in the following order, at least a support, a photosensitive layer, and a mask portion on which an image is formed, through the mask portion to expose the photosensitive layer, and a development step of removing a non-exposed portion of the photosensitive layer, in which the exposure step includes a step of radiating the energy ray in a state in which, from the photosensitive layer side, the mask portion and a film-like optical element are present in this order between an energy source and the photosensitive layer, and the film-like optical element is an element which converges the incident energy ray to enhance directivity and emits the energy ray to the mask portion.

The energy ray is preferably ultraviolet light.

The film-like optical element is preferably a prism sheet or a lenticular lens.

The film-like optical element is preferably formed from glass.

The film-like optical element is preferably formed from a resin.

According to the present invention, it is possible to provide a manufacturing method of a flexographic printing plate, which achieves both a depth of a concave portion and reproducibility of independent dots.

### BRIEF DESCRIPTION OF THE DRAWINGS

FIG. 1 is a schematic diagram showing an example of a manufacturing method of a flexographic printing plate according to an embodiment of the present invention.

FIG. 2 is a schematic cross-sectional view showing an example of a flexographic printing plate precursor used in the manufacturing method of a flexographic printing plate according to the embodiment of the present invention.

FIG. 3 is a schematic cross-sectional view showing another example of a flexographic printing plate precursor used in the manufacturing method of a flexographic printing plate according to the embodiment of the present invention.

FIG. 4 is a schematic cross-sectional view showing a manufacturing method of a mask portion of the example of the flexographic printing plate precursor used in the manufacturing method of a flexographic printing plate according to the embodiment of the present invention.

FIG. 5 is a schematic cross-sectional view showing the mask portion of the example of the flexographic printing plate precursor used in the manufacturing method of a flexographic printing plate according to the embodiment of the present invention.

FIG. 6 is a schematic cross-sectional view showing a state before forming a mask portion of another example of the flexographic printing plate precursor used in the manufacturing method of a flexographic printing plate according to the embodiment of the present invention.

FIG. 7 is a schematic cross-sectional view showing a depth of a concave portion in a case where scattered light is used for exposure of the flexographic printing plate precursor.

FIG. 8 is a schematic cross-sectional view showing independent dots in a case where scattered light is used for exposure of the flexographic printing plate precursor.

FIG. 9 is a schematic cross-sectional view showing a depth of a concave portion in a case where fully collimated light is used for exposure of the flexographic printing plate precursor.

FIG. 10 is a schematic cross-sectional view showing independent dots in a case where fully collimated light is used for exposure of the flexographic printing plate precursor.

FIG. 11 is a schematic cross-sectional view showing a depth of a concave portion in the manufacturing method of a flexographic printing plate according to the embodiment of the present invention.

FIG. 12 is a schematic cross-sectional view showing independent dots in the manufacturing method of a flexographic printing plate according to the embodiment of the present invention.

### DESCRIPTION OF THE PREFERRED EMBODIMENTS

Hereinafter, a manufacturing method of a flexographic printing plate according to an embodiment of the present invention will be described in detail based on suitable embodiments shown in the attached drawings.

The drawings illustrated below are exemplary for explaining the present invention, and the present invention is not limited to the drawings illustrated below.

In the following, “to” indicating the numerical range includes numerical values described on both sides. For example, in a case where ε is a numerical value εα to a numerical value εβ, the range of ε is a range including the numerical value εα and the numerical value εβ, and in mathematical symbols, εα≤ε≤εβ.

Unless otherwise specified, angles such as “parallel” and “orthogonal” include an error range generally allowed in the relevant technical field.

In addition, each component may be used alone or in combination of two or more thereof. Here, in a case where two or more kinds are used in combination for each component, a content with regard to the component indicates the total content thereof, unless otherwise specified.

In addition, “(meth)acryl” represents a notation of “acryl” or “methacryl”, “(meth)acrylate” represents a notation of “acrylate” or “methacrylate”, and “(meth)acryloyl” represents a notation of “acryloyl” or “methacryloyl”.

[Manufacturing Method of Flexographic Printing Plate]

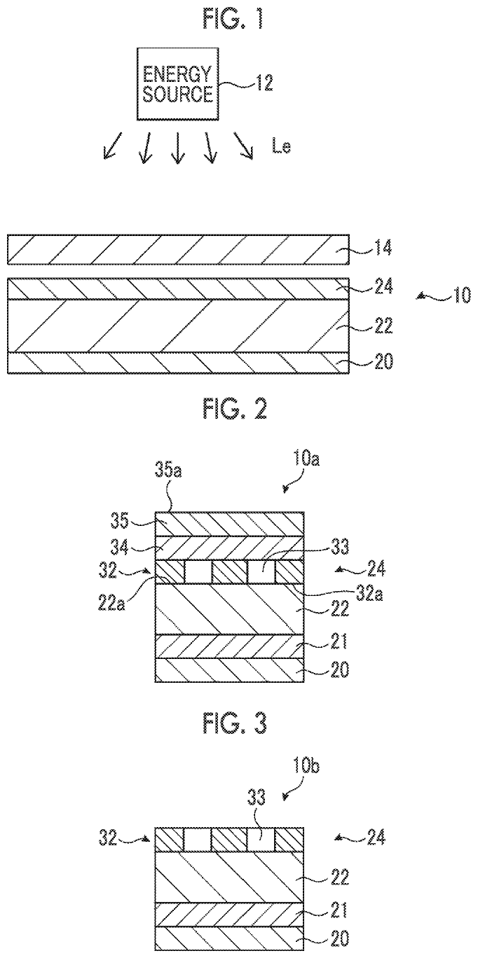

FIG. 1 is a schematic diagram showing an example of the manufacturing method of a flexographic printing plate according to the embodiment of the present invention.

As shown in FIG. 1, the manufacturing method of a flexographic printing plate uses a flexographic printing plate precursor 10 including, in the following order, at least a support 20, a photosensitive layer 22, and a mask portion 24 on which an image is formed.

The manufacturing method of a flexographic printing plate includes an exposure step of irradiating the above-described flexographic printing plate precursor 10 with an energy ray through the mask portion 24, and a development step of removing a non-exposed portion of the photosensitive layer 22.

(Exposure Step)

In the exposure step, an energy ray Le is irradiated from the mask portion 24 in a state in which the mask portion 24 and a film-like optical element 14 are present in this order from the photosensitive layer 22 side between an energy source 12 and the photosensitive layer 22.

The film-like optical element 14 is an element which converges the incident energy ray Le to enhance directivity and emits the energy ray Le, and light having the adjusted directivity is emitted. In a case where scattered light is incident, the film-like optical element 14 emits light having a large amount of components parallel to the scattered light as emitted light. Accordingly, the exposure can be performed using light having a large amount of components of collimated light.

The light emitted by the film-like optical element 14, that is, the light used for the exposure is light in which directivity is adjusted as described above. The light emitted by the film-like optical element 14 includes a component of collimated light, but may include scattered light, and the emitted light is not limited to the collimated light.

As shown in FIG. 1, the film-like optical element 14 is disposed on the mask portion 24 of the flexographic printing plate precursor 10, and the energy source 12 is disposed on the film-like optical element 14.

The flexographic printing plate precursor 10 is to be a flexographic printing plate through the exposure step and the development step. The flexographic printing plate has an image area and a non-image area. The flexographic printing plate precursor 10 will be described later.

[Energy Source]

The energy source 12 irradiates the energy ray Le for exposing the photosensitive layer 22 of the flexographic printing plate precursor 10. As the energy source 12, a radiation source corresponding to the energy ray Le to be irradiated is appropriately used.

As the energy ray Le, ultraviolet light is preferable because a system can be constructed at a relatively low cost. The ultraviolet light is, for example, light having a wavelength of 100 to 400 nm. In a case where the energy ray Le is ultraviolet light, a light source which irradiates the energy source 12 with ultraviolet light is used. For example, as the energy source 12 for irradiating ultraviolet light, a high-pressure mercury lamp, an ultrahigh-pressure mercury lamp, a metal halide lamp, a xenon lamp, a carbon arc lamp, a chemical lamp, LED, or the like, which can perform irradiation with light having a wavelength of 300 to 400 nm, can be usually used. In addition, in order to effectively use the light component reflected by the film-like optical element 14, a reflector may be used. In this case, it is preferable that the energy source is disposed between the reflector and the film-like optical element 14.

In the exposure step, since the film-like optical element 14 is used, scattered light can be used for the energy ray Le, and it is not necessary to control the directivity such as converting the energy ray Le into parallel light.

(Film-Like Optical Element)

In the film-like optical element 14, the energy ray Le irradiated from the energy source 12 is transmitted through the mask portion 24, and the photosensitive layer 22 is irradiated with the energy ray Le through the mask portion 24.

The film-like optical element 14 is an element which has a film shape and changes characteristics of light in a case where the light is transmitted from one surface to the other surface. As described above, the film-like optical element 14 is an element which converges the incident energy ray Le to enhance directivity and emits the energy ray. Therefore, in a case where the scattered light is incident on the film-like optical element 14, the scattered light is converged and the directivity is enhanced, the scattered light is appropriately paralleled, and the scattered light is emitted as light close to collimated light.

A prism or a lens is used for the convergence of the energy ray Le, but the present invention is not limited thereto. The convergence of the energy ray Le is realized, for example, by refracting light.

The directivity is spread of the light. High directivity means that the light does not spread. The light having high directivity is, for example, laser light.

The collimated light is light which is incident on a direction perpendicular to the surface of the flexographic printing plate precursor 10.

It is preferable that the film-like optical element 14 has a characteristic that, in a case where the scattered light is transmitted as the energy ray Le, the directivity of the scattered light is enhanced to change the directivity to a direction close to that of collimated light. That is, it is preferable that the film-like optical element 14 has a characteristic of changing incident light to directivity close to that of parallel light.

The film-like optical element 14 preferably has a characteristic of not absorbing the energy ray Le. Accordingly, the energy ray Le can be effectively used for the exposure.

Specifically, from the viewpoint of enhancing the directivity of the incident energy ray, the film-like optical element 14 is suitably a prism sheet, a lenticular lens, or the like.

The prism sheet is a parallel prism plate in which a plurality of prisms extending in one direction are arranged on a plane with the extending directions aligned.

The lenticular lens is a lens in which cylindrical lenses are arranged on a plane.

The film-like optical elements 14 may be a single unit or a plurality of film-like optical elements. The number of film-like optical elements 14 is appropriately determined according to the characteristics of the emitted light emitted from the film-like optical elements 14. For example, in a case of the prism sheet, two prism sheets can be laminated and used with the extending directions of the prisms orthogonal to each other. In addition, in a case of the lenticular lens, two lenticular lenses can be laminated and used with the extending directions of the cylindrical lenses orthogonal to each other.

The film-like optical element 14 is formed from, for example, glass. As the glass, glass used for manufacturing in a microlens array or the like is appropriately used, and optical glass, quartz glass, or the like is used. The glass preferably has a characteristic of not absorbing light in a wavelength range of the energy ray Le used for the exposure. Accordingly, the energy ray Le can be effectively used for the exposure.

In addition, in a case where the film-like optical element 14 is formed from a resin, the film-like optical element 14 is formed, for example, by thermal polymerization or melt molding.

In a case where the film-like optical element 14 formed from a resin is formed by thermal polymerization, the resin is preferably polymerized by addition polymerization, and for example, an acrylic resin, polyvinyl chloride, polyacrylonitrile, polystyrene, ABS resin (a general term for copolymer synthetic resins of acrylonitrile, butadiene, and styrene), or the like can be used.

In a case where the film-like optical element 14 formed from a resin is formed by melt molding, the resin is not particularly limited in a polymerization method, and for example, an acrylic resin, polyvinyl chloride, polycarbonate, polyethylene terephthalate, polyacrylonitrile, polystyrene, polypropylene, an ABS resin, or the like can be used.

It is preferable that the thermally polymerized resin and the melt-molded resin, which form the film-like optical element 14, have the characteristic of not absorbing light in a wavelength range of the energy ray Le used for the exposure. Accordingly, the energy ray Le can be effectively used for the exposure.

In addition, the film-like optical element 14 can be formed from, for example, an UV-cured resin in which an initiator having absorption in a ultraviolet wavelength range different from the wavelength range of the energy ray Le is used.

Examples of the UV-cured resin in which an initiator having absorption in a ultraviolet wavelength range different from the wavelength range of the energy ray Le is used include an acrylic resin, polyvinyl chloride, polyacrylonitrile, polystyrene, and an ABS resin.

(Configuration of Flexographic Printing Plate Precursor)

FIG. 2 is a schematic cross-sectional view showing an example of the flexographic printing plate precursor used in the manufacturing method of a flexographic printing plate according to the embodiment of the present invention, and FIG. 3 is a schematic cross-sectional view showing another example of the flexographic printing plate precursor used in the manufacturing method of a flexographic printing plate according to the embodiment of the present invention. In FIG. 2 and FIG. 3, the same components as those of the flexographic printing plate precursor 10 shown in FIG. 1 are designated by the same reference numerals, and detailed description thereof will be omitted. In the present invention, the configuration of the flexographic printing plate precursor is not limited to the following.

A flexographic printing plate precursor 10a shown in FIG. 2 is an example of an analog type flexographic printing plate precursor. The flexographic printing plate precursor 10a is a form to be exposed and has the mask portion 24. In the flexographic printing plate precursor 10a, a pattern showing an image is formed on the mask portion 24. That is, an image is formed on the mask portion 24.

In the flexographic printing plate precursor 10a, an adhesive layer 21 and the photosensitive layer 22 are arranged on the support 20 in this order. An infrared ablation layer 32, an adhesive layer 34, and a carrier sheet 35 are arranged in this order on a surface 22a of the photosensitive layer 22. The mask portion 24 is composed of the infrared ablation layer 32, the adhesive layer 34, and the carrier sheet 35 on the surface 22a of the photosensitive layer 22.

The infrared ablation layer 32 is a layer capable of removing a portion irradiated with infrared laser, and the infrared ablation layer 32 itself is a layer having a function of shielding transmission of ultraviolet rays at a practical level. A pattern showing an image is formed on the infrared ablation layer 32, and the infrared ablation layer 32 has an opening 33 based on the pattern. The mask portion 24 on which the image is formed has the infrared ablation layer 32 having the opening 33 based on the pattern showing the image. A negative film may be used instead of the infrared ablation layer 32.

In the flexographic printing plate precursor 10a, the film-like optical element 14 is disposed on a surface 35a of the carrier sheet 35 and is exposed.

The adhesive layer 21 and the adhesive layer 34 are, for example, an optically transparent pressure-sensitive adhesive (OCA). The carrier sheet 35 is, for example, a polyethylene terephthalate (PET) film.

A flexographic printing plate precursor 10b shown in FIG. 3 is an example of a LAM type flexographic printing plate precursor. The flexographic printing plate precursor 10b is a form to be exposed and has the mask portion 24. In the flexographic printing plate precursor 10b, a pattern showing an image is formed on the mask portion 24. That is, an image is formed on the mask portion 24.

In the flexographic printing plate precursor 10b, the adhesive layer 21 and the photosensitive layer 22 are arranged on the support 20 in this order. The infrared ablation layer 32 is disposed on the surface 22a of the photosensitive layer 22. The mask portion 24 is composed of the infrared ablation layer 32 on the surface 22a of the photosensitive layer 22.

A pattern showing an image is formed on the infrared ablation layer 32, and the infrared ablation layer 32 has an opening 33 based on the pattern showing the image.

The pattern of the mask portion 24 of the flexographic printing plate precursor 10a shown in FIG. 2 is formed, for example, as follows.

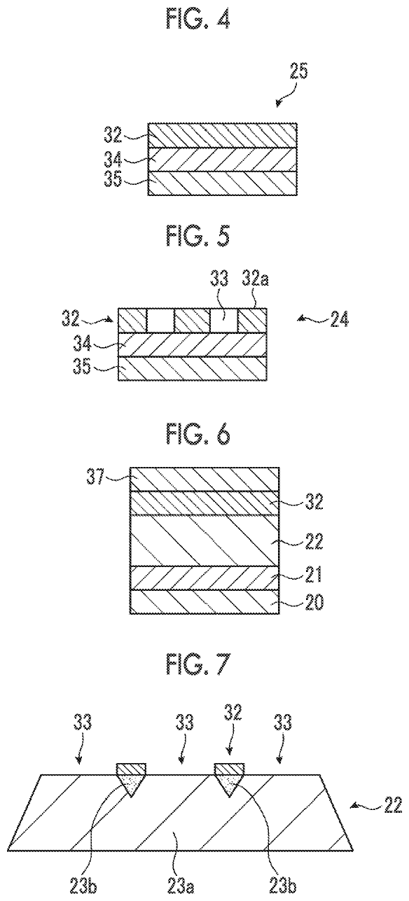

As shown in FIG. 4, the adhesive layer 34 and the infrared ablation layer 32 are laminated on the carrier sheet 35 in this order, and a laminate 25 is subjected to pattern exposure using infrared rays from the infrared ablation layer 32 side. Accordingly, as shown in FIG. 5, the mask portion 24 in which the opening 33 based on the pattern showing the image is formed in the infrared ablation layer 32 is obtained. By adhering the surface 32a of the infrared ablation layer 32 of the mask portion 24, shown in FIG. 5, and the surface 22a of the photosensitive layer 22, shown in FIG. 2, the flexographic printing plate precursor 10a to be subjected to the exposure step, shown in FIG. 2, is obtained.

Here, FIG. 4 is a schematic cross-sectional view showing a manufacturing method of the mask portion of the example of the flexographic printing plate precursor used in the manufacturing method of a flexographic printing plate according to the embodiment of the present invention, and FIG. 5 is a schematic cross-sectional view showing the mask portion of the example of the flexographic printing plate precursor used in the manufacturing method of a flexographic printing plate according to the embodiment of the present invention. In FIG. 4 and FIG. 5, the same components as those of the flexographic printing plate precursor 10a shown in FIG. 2 are designated by the same reference numerals, and detailed description thereof will be omitted.

As shown in FIG. 6, a protective sheet 37 is provided on the flexographic printing plate precursor 10b shown in FIG. 3 before the exposure. At the time of exposure, the protective sheet 37 is peeled off, and the infrared ablation layer 32 is subjected to the pattern exposure using infrared rays from the infrared ablation layer 32 side. Accordingly, as shown in FIG. 3, the mask portion 24 in which the opening 33 based on the pattern showing the image is formed in the infrared ablation layer 32 is obtained. The protective sheet 37 is, for example, a PET film.

Here, FIG. 6 is a schematic cross-sectional view showing a state before forming a mask portion of another example of the flexographic printing plate precursor used in the manufacturing method of a flexographic printing plate according to the embodiment of the present invention. In FIG. 6, the same components as those of the flexographic printing plate precursor 10b shown in FIG. 3 are designated by the same reference numerals, and detailed description thereof will be omitted.

(Development Step)

By the exposure step, in the photosensitive layer 22, the exposed portion is cured and exists as a cured portion, and a non-exposed portion is not cured and exists as an uncured portion. After undergoing the development step, the exposed portion becomes an image area, and the non-exposed portion becomes a non-image area.

In the development step, the non-exposed portion of the photosensitive layer is removed in a developer to obtain the image area which is the exposed portion. An organic solvent or a water-based developer (aqueous developer) is used as the developer. As the aqueous developer, a developer obtained by adding a surfactant, a pH (potential of hydrogen) adjuster, or the like as necessary to water is used. For example, the non-exposed portion of the photosensitive layer is removed by washing out the non-exposed portion using a spray type developing device, a brush-type washing machine, or the like. Next, the flexographic printing plate precursor is taken out from the developer and dried.

As the development step, thermal development in which the uncured portion is transferred to a nonwoven fabric by closely attaching the uncured portion to the nonwoven fabric and applying heat can also be used. Since no developer is used in the thermal development, drying is not necessary.

Next, the entire dried flexographic printing plate precursor is irradiated with ultraviolet rays as necessary (post-exposure). As a result, a flexographic printing plate having the image area and the non-image area can be obtained.

Since the flexographic printing plate precursor, which is developed using the water-based developer, tends to scatter light, it is more preferable to use the film-like optical element 14 in the exposure step as described above.

(Depth of Concave Portion and Independent Dots)

Hereinafter, a depth of a concave portion and independent dots in the exposure step will be described.

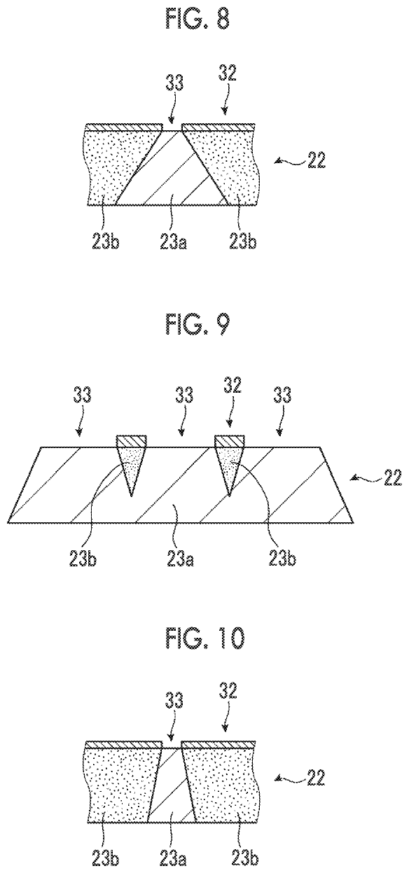

FIG. 7 is a schematic cross-sectional view showing the depth of the concave portion in a case where scattered light is used for the exposure of the flexographic printing plate precursor, and FIG. 8 is a schematic cross-sectional view showing the independent dots in a case where scattered light is used for the exposure of the flexographic printing plate precursor. In addition, FIG. 9 is a schematic cross-sectional view showing the depth of the concave portion in a case where fully collimated light is used for the exposure of the flexographic printing plate precursor, and FIG. 10 is a schematic cross-sectional view showing the independent dots in a case where fully collimated light is used for the exposure of the flexographic printing plate precursor. In FIGS. 7 to 10, the same components as those of the flexographic printing plate precursor 10 shown in FIG. 1 are designated by the same reference numerals, and detailed description thereof will be omitted.

In a case where the scattered light is used in the exposure step, due to halation, as shown in FIG. 7, in the photosensitive layer 22, a bottom area of a non-exposed portion 23b below the infrared ablation layer 32 is small, and the depth of the concave portion is insufficient.

In addition, as shown in FIG. 8, in the opening 33 corresponding to the independent dots, due to the halation, in the photosensitive layer 22, an exposed portion 23a below the opening 33 is large, and the exposed portion 23a is less likely to have the independent dots during the development. However, in a case where the scattered light is used in the exposure step, the depth of the concave portion is insufficient.

In a case where the fully collimated light is used in the exposure step, as shown in FIG. 9, in the photosensitive layer 22, the non-exposed portion 23b below the infrared ablation layer 32 is large, and the depth of the concave portion is obtained.

In addition, in a case of using the fully collimated light, as shown in FIG. 10, in the opening 33 corresponding to the independent dots, in the photosensitive layer 22, a bottom area of the exposed portion 23a below the opening 33 is small, and the exposed portion 23a tends to lose the independent dots during the development. As a result, reproducibility of the independent dots of the flexographic printing plate is deteriorated. The fully collimated light is light which is composed of collimated light and includes almost no scattered light.

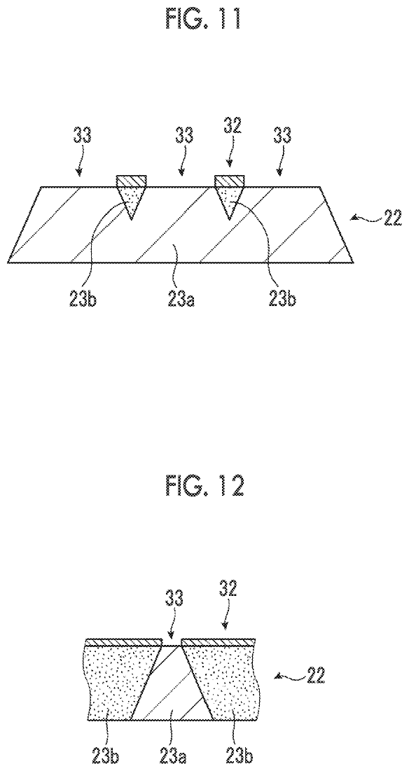

FIG. 11 is a schematic cross-sectional view showing the depth of the concave portion in the manufacturing method of a flexographic printing plate according to the embodiment of the present invention, and FIG. 12 is a schematic cross-sectional view showing the independent dots in the manufacturing method of a flexographic printing plate according to the embodiment of the present invention. In FIG. 11 and FIG. 12, the same components as those of the flexographic printing plate precursor 10 shown in FIG. 1 are designated by the same reference numerals, and detailed description thereof will be omitted.

The film-like optical element 14 is used in the exposure step. By using the film-like optical element 14, for example, in a case where ultraviolet light in a scattered light state is used for the exposure, the ultraviolet light incident on the film-like optical element 14 is converged on the mask portion 24 to enhance the directivity, and the photosensitive layer 22 is exposed to the light in which the directivity is adjusted. As a result, as shown in FIG. 11, in the photosensitive layer 22, the exposed portion 23a is formed below the opening 33 of the infrared ablation layer 32, and the non-exposed portion 23b is formed below the infrared ablation layer 32. The exposed portion 23a becomes the cured portion, and the non-exposed portion 23b becomes the uncured portion.

In the development step, the non-exposed portion 23b of the photosensitive layer 22 is removed, and the exposed portion 23a remains. Since the energy ray Le used for the exposure is the light in which the directivity is adjusted, the halation is suppressed as compared with a case where the scattered light is used, and a practically sufficient depth of the concave portion can be obtained.

In addition, as shown in FIG. 12, in a case of the opening 33 corresponding to the independent dots, in the photosensitive layer 22, the exposed portion 23a is formed below the opening 33, and the non-exposed portion 23b is formed below the infrared ablation layer 32. The non-exposed portion 23b of the photosensitive layer 22 is removed by the development step, and the exposed portion 23a remains. Since the energy ray Le used for the exposure is the light in which the directivity is adjusted, the exposed portion 23a is less likely to have the independent dots during the development as compared with a case where the fully collimated light is used. As a result, the reproducibility of the independent dots of the flexographic printing plate is improved as compared with the case of using the fully collimated light.

Accordingly, in the manufacturing method of a flexographic printing plate, it is possible to achieve both the depth of the concave portion and the reproducibility of the independent dots by eliminating an insufficient depth of the concave portion and increasing the exposed portion, that is, increasing a cured region, by exposing periphery of the independent dots.

Hereinafter, the flexographic printing plate precursor will be described in more detail. In the present invention, the flexographic printing plate precursor is not limited to the following.

[Flexographic Printing Plate Precursor]

The flexographic printing plate precursor (hereinafter, also referred to as “printing plate precursor”) contains a binder, a monomer, and a photopolymerization initiator.

Hereinafter, first, the photosensitive layer included in the printing plate precursor will be described.

[Photosensitive Layer]

The photosensitive layer included in the printing plate precursor (hereinafter, also referred to as “photosensitive layer”) contains a binder, a monomer, and a photopolymerization initiator. Hereinafter, each component contained in the photosensitive layer will be described.

<Binder>

The binder contained in the photosensitive layer is not particularly limited, and examples thereof include a thermoplastic polymer.

The thermoplastic polymer is not particularly limited as long as the thermoplastic polymer is a polymer exhibiting thermoplasticity, and specific examples thereof include a polystyrene resin, a polyester resin, a polyamide resin, a polysulfone resin, a polyethersulfone resin, a polyimide resin, an acrylic resin, an acetal resin, an epoxy resin, a polycarbonate resin, rubbers, and a thermoplastic elastomer. These may be used alone or in combination of two or more.

Among these, from the reason that an elastic and flexible film can be easily formed, a rubber or a thermoplastic elastomer is preferable, a rubber is more preferable, and a diene-based rubber is still more preferable.

As the above-described rubber, in order to secure elasticity of the flexographic printing plate precursor, a non-fluid rubber which does not have fluidity is preferable.

Specific examples thereof include butadiene rubber (BR), nitrile rubber (NBR), acrylic rubber, epichlorohydrin rubber, urethane rubber, isoprene rubber, styrene isoprene rubber, styrene butadiene rubber (SBR), ethylene-propylene copolymer, and chlorinated polyethylene. These may be used alone or in combination of two or more. Among these, from the reason that water developability is improved, or from the viewpoint of drying properties and image reproducibility, at least one rubber selected from the group consisting of butadiene rubber (BR), styrene butadiene rubber (SBR), and nitrile rubber (NBR) is preferable, and from the viewpoint of water-based ink resistance, butadiene rubber or styrene butadiene rubber is more preferable.

Examples of the above-described thermoplastic elastomer include a polybutadiene-based thermoplastic elastomer (PB), a polyisoprene-based thermoplastic elastomer, a polyolefin-based thermoplastic elastomer, and an acrylic thermoplastic elastomer. Specific examples thereof include polystyrene-polybutadiene (SB), polystyrene-polybutadiene-polystyrene (SBS), polystyrene-polyisoprene-polystyrene (SIS), polystyrene-polyethylene/polybutylene-polystyrene (SEBS), acrylonitrile butadiene styrene copolymer (ABS), acrylic acid ester rubber (ACM), acrylonitrile-chlorinated polyethylene-styrene copolymer (ACS), acrylonitrile-styrene copolymer, syndiotactic 1,2-polybutadiene, and methyl polymethacrylate-butyl polyacrylate-methyl polymethacrylate. Among these, from the reason that water developability is improved, or from the viewpoint of drying properties and image reproducibility, PB, SBS, or SIS is particularly preferable.

The content of the binder is preferably 1% to 50% by mass, more preferably 5% to 40% by mass, and still more preferably 7% to 30% by mass with respect to the total mass of solid content in the photosensitive layer.

<Monomer>

As described above, the photosensitive layer according to the present invention contains a monomer.

The monomer is not particularly limited, but from the reason that the obtained effects of the present invention are more excellent, a monofunctional monomer, a bifunctional monomer, or a monomer having a functional group higher than two may be used alone or in combination.

(Monofunctional Monomer)

From the reason that the effects of the present invention are more excellent, the above-described monofunctional monomer is preferably a compound having one ethylenically unsaturated group. Specific examples of the above-described ethylenically unsaturated group are as described above.

Examples of the compound having one ethylenically unsaturated group include
N-vinyl compounds such as N-vinylformamide;
(meth)acrylamide compounds such as (meth)acrylamide, N-methylol (meth)acrylamide, diacetone (meth)acrylamide, N,N-dimethyl (meth)acrylamide, N,N-diethyl (meth)acrylamide, N-isopropyl (meth)acrylamide, (meth)acryloylmorpholine, and (meth)acrylamide;
(meth)acrylate compounds such as 2-hydroxyethyl (meth)acrylate, butoxyethyl (meth)acrylate, carbitol (meth)acrylate, cyclohexyl (meth)acrylate, tetrahydrofurfuryl (meth)acrylate, benzyl (meth)acrylate, tridecyl (meth)acrylate, 2-phenoxyethyl (meth)acrylate, glycidyl (meth)acrylate, isobornyl (meth)acrylate, dicyclopentenyl (meth)acrylate, dicyclopentenyl oxyethyl (meth)acrylate, dicyclopentanyl (meth)acrylate, 2-hydroxy-3-phenoxypropyl (meth)acrylate, 2-(meth)) acryloyloxyethyl phthalate, methoxy-polyethylene glycol (meth)acrylate, 2-(meth)acryloyloxyethyl-2-hydroxyethyl phthalate, 2-(2-ethoxyethoxy)ethyl (meth)acrylate, 2-methoxyethyl (meth)acrylate, 3-methoxybutyl (meth)acrylate, ethoxylated phenyl (meth)acrylate, 2-(meth)acryloyloxyethyl succinic acid, nonylphenol EO-adduct (meth)acrylate, phenoxy-polyethylene glycol (meth)acrylate, 2-(meth)acryloyloxyethylhexahydrophthalic acid, lactone-modified (meth)acrylate, stearyl (meth)acrylate, isoamyl (meth)acrylate, isomyristyl (meth)acrylate, isostearyl (meth)acrylate, and cyclic trimethylolpropane formal (meth)acrylate; and
monovinyl ether compounds such as methyl vinyl ether, ethyl vinyl ether, n-propyl vinyl ether, isopropyl vinyl ether, n-butyl vinyl ether, isobutyl vinyl ether, t-butyl vinyl ether, n-octadecyl vinyl ether, 2-ethylhexyl vinyl ether, n-nonyl vinyl ether, dodecyl vinyl ether, octadecyl vinyl ether, cyclohexyl vinyl ether, cyclohexyl methyl vinyl ether, 4-methylcyclohexyl methyl vinyl ether, benzyl vinyl ether, dicyclopentenyl vinyl ether, 2-dicyclopentenoxyethyl vinyl ether, methoxyethyl vinyl ether, ethoxyethyl vinyl ether, butoxyethyl vinyl ether, methoxyethoxyethyl vinyl ether, ethoxyethoxyethyl vinyl ether, methoxypolyethylene glycol vinyl ether, tetrahydrofurfuryl vinyl ether, 2-hydroxyethyl vinyl ether, 2-hydroxypropyl vinyl ether, 4-hydroxybutyl vinyl ether, 4-hydroxymethyl cyclohexyl methyl vinyl ether, diethylene glycol monovinyl ether, polyethylene glycol vinyl ether, chlorethyl vinyl ether, chlorobutyl vinyl ether, chloroethoxyethyl vinyl ether, phenylethyl vinyl ether, phenoxypolyethylene glycol vinyl ether, cyclohexanedimethanol monovinyl ether, and isopropenyl ether-O-propylene carbonate.
EO represents ethylene oxide.

From the reason that the effects of the present invention are more excellent, a content of the monofunctional monomer in the photosensitive layer according to the present invention is preferably 0.1% to 30% by mass, and more preferably 1% to 10% by mass with respect to the total solid content of the photosensitive layer according to the present invention.

(Bifunctional Monomer)

From the reason that the effects of the present invention are more excellent, the above-described bifunctional monomer is preferably a compound having two ethylenically unsaturated groups.

Examples of the ethylenically unsaturated group include a radically polymerizable group such as an acryloyl group, a methacryloyl group, a vinyl group, a styryl group, and an allyl group, and among these, an acryloyl group, a methacryloyl group, or C(O)OCH═CH₂ is preferable, and an acryloyl group or a methacryloyl group is more preferable.

Examples of the compound having two ethylenically unsaturated groups include
glycol di(meth)acrylate compounds such as ethyleneglycol di(meth)acrylate, diethyleneglycol di(meth)acrylate, triethyleneglycol di(meth)acrylate, tetraethyleneglycol di(meth)acrylate, polyethyleneglycol di(meth)acrylate, propyleneglycol di(meth)acrylate, dipropyleneglycol di(meth)acrylate, tripropyleneglycol di(meth)acrylate, tetrapropyleneglycol di(meth)acrylate, polypropyleneglycol di(meth)acrylate, ethoxylated neopentylglycol di(meth)acrylate, and propoxylated neopentylglycol di(meth)acrylate;
divinyl ether compounds such as ethyleneglycol divinyl ether, diethyleneglycol divinyl ether, triethyleneglycol divinyl ether, propyleneglycol divinyl ether, dipropyleneglycol divinyl ether, butanediol divinyl ether, hexanediol divinyl ether, and cyclohexanedimethanol divinyl ether; and
di(meth)acrylate compounds of bisphenol A such as bisphenol A diglycidyl ether (meth)acrylic acid adduct, modified bisphenol A di(meth)acrylate, bisphenol A PO-adducted di(meth)acrylate, and bisphenol A EO-adducted di(meth)acrylate.
PO represents propylene oxide and EO represents ethylene oxide.

From the reason that the effects of the present invention are more excellent, a content of the bifunctional monomer in the photosensitive layer according to the present invention is preferably 0.1% to 30% by mass with respect to the total solid content of the photosensitive layer according to the present invention.

<Photopolymerization Initiator>

From the reason that the effects of the present invention are more excellent, the photosensitive layer according to the present invention preferably contains a photopolymerization initiator.

The photopolymerization initiator is not particularly limited, and examples thereof include photopolymerization initiators such as alkylphenones, acetophenones, benzoin ethers, benzophenones, thioxanthones, anthraquinones, benzyls, and biacetyls.

More specific examples thereof include benzyl dimethyl ketal, 2-hydroxy-2-methyl-1-phenyl-propan-1-one, methyl-o-benzoylbenzoate, and 1-hydroxycyclohexyl phenyl ketone.

From the viewpoint of sensitivity and the like, a content of the photopolymerization initiator in the photosensitive layer according to the present invention is preferably 0.3% to 15% by mass and more preferably 0.5% to 10% by mass with respect to the total solid content of the photosensitive layer according to the present invention.

<Water-Dispersible Particles>

The photosensitive layer can contain water-dispersible particles in order to enable the development in the aqueous developer.

The water-dispersible particles are not particularly limited, but from the reason that water dispersibility is more excellent, printing durability, handleability, and rear end ink receptivity of the obtained flexographic printing plate are more excellent, development reproducibility and solid quality are excellent, and printing pressure latitude is wider, the water-dispersible particles are preferably a polymer. Hereinafter, the “water dispersibility is more excellent, printing durability, handleability, and rear end ink receptivity of the obtained flexographic printing plate are more excellent, development reproducibility and solid quality are excellent, and printing pressure latitude is wider” is also referred to as “effects as the flexographic printing plate precursor are more excellent”.

Specific examples of the above-described polymer include diene-based polymers (for example, polybutadiene, natural rubber, styrene-butadiene copolymer, acrylonitrile-butadiene copolymer, methyl methacrylate-butadiene copolymer, polychloroprene, and polyisoprene), polyurethane, vinylpyridine polymer, butyl polymer, thiokol polymer, acrylate polymer, and a polymer obtained by copolymerizing these polymers with other components such as acrylic acid and methacrylic acid. These may be used alone or in combination of two or more.

From the reason that the effects as the flexographic printing plate precursor are more excellent, the above-described polymer is preferably a diene-based polymer and more preferably polybutadiene.

It is preferable that the above-described polymer does not have a reactive functional group (for example, a (meth)acryloyloxy group) at both terminals.

From the reason that the effects as the flexographic printing plate precursor are more excellent, the above-described polymer is a polymer obtained by removing water from water-dispersible latex. Specific examples of the above-described water-dispersible latex include water-dispersible latex of specific examples of the above-described polymer.

From the reason that the effects as the flexographic printing plate precursor are more excellent, a content of the water-dispersible particles in the photosensitive layer is preferably 5% to 80% by mass, more preferably 10% to 50% by mass, and still more preferably 20% to 40% by mass with respect to the total solid content of the photosensitive layer.

(Plasticizer)

From the reason that flexibility is improved, the photosensitive layer may contain a plasticizer.

Specific examples of the plasticizer include liquid rubber, oil, polyester, and phosphoric acid-based compounds.

Specific examples of the liquid rubber include liquid polybutadiene, liquid polyisoprene, and compounds in which these compounds are modified with maleic acid or an epoxy group.

Specific examples of the oil include paraffin, naphthene, and aroma.

Specific examples of the polyester include adipic acid-based polyester.

Specific examples of the phosphoric acid-based compound include phosphoric acid ester.

From the reason that the flexibility is further improved, a content of the plasticizer in the photosensitive layer is preferably 0.1% to 40% by mass, and more preferably 5% to 30% by mass with respect to the total solid content of the photosensitive layer.

(Surfactant)

From the viewpoint of further improving the water developability, the photosensitive layer may contain a surfactant.

Examples of the surfactant include a cationic surfactant, an anionic surfactant, and a nonionic surfactant. Among these, from the reason that the effects as the flexographic printing plate precursor are more excellent, an anionic surfactant is preferable.

Specific examples of the anionic surfactant include
aliphatic carboxylates such as sodium laurate, and sodium oleate;
higher alcohol sulfate salts such as sodium lauryl sulfate, sodium cetyl sulfate, and sodium oleyl sulfate;
polyoxyethylene alkyl ether sulfate ester salts such as sodium polyoxyethylene lauryl ether sulfate;
polyoxyethylene alkyl allyl ether sulfate ester salts such as sodium polyoxyethylene octyl phenyl ether sulfate and sodium polyoxyethylene nonyl phenyl ether sulfate;
alkyl sulfonates such as alkyl diphenyl ether disulfonate, sodium dodecyl sulfonate, and sodium dialkyl sulfosuccinate;
alkyl allyl sulfonates such as alkyl disulfonate, sodium dodecyl benzene sulfonate, sodium dibutyl naphthalene sulfonate, and sodium triisopropyl naphthalene sulfonate;
higher alcohol phosphate ester salts such as disodium lauryl phosphate monoester, and sodium lauryl phosphate diester; and
polyoxyethylene alkyl ether phosphate ester salts such as disodium polyoxyethylene lauryl ether phosphate monoester, and sodium polyoxyethylene lauryl ether phosphate diester.

These may be used alone or in combination of two or more.

Among these, from the reason that the water developability is further improved, sulfonic acid-based surfactants such as alkyl sulfonate and alkyl allyl sulfonate are preferable.

From the viewpoint of developability and drying properties after development, a content of the surfactant in the photosensitive layer is preferably 0.1% to 20% by mass, and more preferably 1% to 10% by mass with respect to the total solid content of the photosensitive layer.

(Thermal Polymerization Inhibitor)

From the viewpoint of improving heat stability during kneading and improving storage stability, the photosensitive layer can contain a thermal polymerization inhibitor (stabilizer).

Examples of the thermal polymerization inhibitor include phenols, hydroquinones, and catechols.

From the reason that the effects as the flexographic printing plate precursor are more excellent, a content of the thermal polymerization inhibitor in the photosensitive layer is preferably 0.001% to 5% by mass with respect to the total solid content of the photosensitive layer.

(Other Additives)

To the extent that the effects as the flexographic printing plate precursor are not impaired, other additives such as an ultraviolet absorber, a dye, a pigment, an antifoaming agent, and a fragrance can be appropriately added to the photosensitive layer, for the purpose of improving various properties.

<Method for Producing Photosensitive Layer>

A method for producing the photosensitive layer included in the printing plate precursor according to the embodiment of the present invention is not particularly limited, and examples thereof include a method of preparing a composition (photosensitive resin composition) containing each of the above-described components and applying the composition to a support or the like.

[Suitable Aspect]

From the reason that the effects as the flexographic printing plate precursor are more excellent, the printing plate precursor is preferably a so-called analog type printing plate precursor in which a negative film (film on which an image is already formed) is closely attached to the photosensitive layer at the time of use, or a LAM type printing plate precursor, in which an infrared ablation layer is closely attached to the photosensitive layer in advance, the LAM type being included in a so-called computer to plate (CTP) type.

From the reason that the effects as the flexographic printing plate precursor are more excellent, it is preferable that the analog type printing plate precursor is a printing plate precursor in which an adhesive layer composed of an adhesive or the like which adheres the support and the photosensitive layer, the photosensitive layer, an anti-adhesion layer to prevent the surface of the photosensitive layer from adhering, and a protective film preventing scratches on the photosensitive layer before use are laminated on the support in this order.

In the analog type printing plate precursor, the protective film is peeled off at the time of use, and the negative film on which an image is formed in advance is closely attached to the exposed anti-adhesion layer.

Examples of the above-described support include those shown below.

[Support]

A material used for the support included in the flexographic printing plate precursor according to the embodiment of the present invention is not particularly limited, and a support with high dimensional stability is preferably used. Examples thereof include metals such as steel, stainless steel, and aluminum; polyester (for example, polyethylene terephthalate (PET), polybutylene terephthalate (PBT), polyethylene naphthalate (PEN), polyimide (PI), polyamide, liquid crystal polymer (LCP), and polyacrylonitrile (PAN)); plastic resins such as polyvinyl chloride; synthetic rubber such as styrene-butadiene rubber; glass fiber reinforced plastic resin (such as epoxy resin and phenolic resin); and cloth and paper.

From the viewpoint of dimensional stability and availability, the support is preferably a polymer film or cloth, and more preferably a polymer film. The morphology of the support is determined by whether the polymer layer is sheet-like or sleeve-like.

As the cloth, plain or twill weave fabrics and various knitted fabrics of natural fibers such as cotton, linen, silk, and wool or synthetic fibers such as acetate, vinylon, vinylidene, polyvinyl chloride, acrylic, polypropylene, polyethylene, polyurethane, fluorine filament, polyclar, rayon, nylon, polyamide, and polyester, or nonwoven fabrics can be used.

Examples of the polymer film include a film formed of various polymers such as polyester (for example, polyethylene terephthalate (PET), polybutylene terephthalate (PBT), polyethylene naphthalate (PEN), polyimide (PI), polyamide, liquid crystal polymer (LCP), and polyacrylonitrile (PAN)), plastic resins such as polyvinyl chloride, synthetic rubber such as styrene-butadiene rubber, and glass fiber reinforced plastic resin (such as epoxy resin and phenolic resin). Among these, from the viewpoint of dimensional stability and the like, a polyester film is preferable.

Examples of the above-described polyester film include a PET film, a PBT film, and a PEN film, and from the viewpoint of dimensional stability and the like, a polyethylene terephthalate (PET) film is preferable.

A thickness of the support is not particularly limited, but from the viewpoint of dimensional stability and handleability, it is preferably 5 to 3,000 μm, more preferably 50 to 2,000 μm, and still more preferably 100 to 1,000 μm.

The analog type printing plate precursor can be manufactured by, for example, applying an adhesive in advance to one surface of the support and applying an anti-adhesion agent in advance to one surface of the protective film, interposing the above-described photosensitive resin composition between a support to which the adhesive is applied in advance and a protective film to which the anti-adhesion agent is applied in advance, and pressing the printing plate precursor such that a thickness of the photosensitive layer is a predetermined thickness.

The LAM type printing plate precursor is different from the analog type printing plate precursor in that the LAM type printing plate precursor has an infrared ablation layer between the photosensitive layer and the protective film, and other configurations are the same as the analog type printing plate precursor. That is, the adhesive layer, the photosensitive layer, the infrared ablation layer, and the protective film are laminated on the support in this order. In the LAM type printing plate precursor, the protective film is peeled off at the time of use to expose the infrared ablation layer.

The infrared ablation layer is a layer capable of removing a portion irradiated by an infrared laser, and the infrared ablation layer itself is a layer which also has a function of blocking the transmission of ultraviolet rays at a practical level. By forming an image on the infrared ablation layer, the infrared ablation layer can serve as a negative film or a positive film.

The infrared ablation layer is mainly composed of a binder such as resin and rubber, an infrared absorbing substance, an ultraviolet absorbing substance, a plasticizer, and the like. The infrared ablation layer can be manufactured by, for example, dissolving the above-described materials in a solvent, applying the solution to a base material, and drying the solution to remove the solvent.

The LAM type printing plate precursor can be manufactured by, for example, applying an adhesive in advance to one surface of the support and coating one surface of the protective film with an infrared ablation layer in advance, interposing the above-described photosensitive resin composition between the support to which the adhesive is applied in advance and the protective film which is coated with the infrared ablation layer in advance, and pressing the printing plate precursor such that a thickness of the photosensitive layer is a predetermined thickness.

In any of the printing plate precursors, from the reason that the effects as the flexographic printing plate precursor are more excellent, a thickness of the photosensitive layer is preferably in a range of 0.01 to 10 mm. In a case where the thickness of the photosensitive layer is 0.01 mm or more, a sufficient relief depth can be secured. The relief depth is a difference in height between a printed portion (relief surface) and a non-printed portion (back surface) of the flexographic printing plate.

[Infrared Ablation Layer]

The infrared ablation layer included in the flexographic printing plate precursor is a portion serving as a mask which covers the surface of the photosensitive layer.

In addition, the infrared ablation layer is a portion which can be removed by an infrared laser, and the unremoved portion shields (absorbs) ultraviolet light to mask the photosensitive layer below the unremoved portion from not being irradiated with the ultraviolet light.

Such an infrared ablation layer can be formed using a resin composition containing a binder and an infrared absorbing substance.

<Binder>

The binder is, for example, a resin or a rubber as described above.

The resin is preferably a (meth)acrylic resin.

In addition, as the rubber, butadiene rubber (BR), acrylonitrile butadiene rubber (NBR), or styrene butadiene rubber (SBR) is preferable, and acrylonitrile butadiene rubber (NBR) is more preferable.

<Infrared Absorbing Substance>

The infrared absorbing substance contained in the resin composition is not particularly limited as long as it is a substance which can absorb infrared rays and convert the infrared rays into heat.

Specific examples of the infrared absorbing substance include black pigments (for example, carbon black, aniline black, cyanine black, and the like), green pigments (for example, phthalocyanine, naphthalocyanine, and the like), rhodamine coloring agents, naphthoquinone-based coloring agents, polymethine dyes, diimmonium salts, azoimonium-based coloring agents, chalcogen-based coloring agents, carbon graphite, iron powder, diamine-based metal complexes, dithiol-based metal complexes, phenolthiol-based metal complexes, mercaptophenol-based metal complexes, aryl aluminum metal salts, crystal water-containing inorganic compounds, copper sulfate, metal oxides (for example, cobalt oxide, tungsten oxide, and the like), and metal powders (for example, bismuth, tin, tellurium, aluminum, and the like).

Among these, from the viewpoint of having an ultraviolet absorbing function and the like, carbon black, carbon graphite, or the like is preferable.

The infrared ablation layer may contain various additives in addition to the binder and the infrared absorbing substance described above.

Examples of such as additive include a surfactant, a plasticizer, an ultraviolet absorbing substance, a peeling agent, a dye, a pigment, an antifoaming agent, and a fragrance.

A method for producing the infrared ablation layer is not particularly limited, and examples thereof include a method of preparing a resin composition containing each of the above-described components and applying the resin composition to the above-described interlayer.

A film thickness of the infrared ablation layer is preferably 0.1 to 6 μm and more preferably 0.5 to 3

[Flexographic Printing Plate]

The flexographic printing plate is obtained by the above-described manufacturing method of a flexographic printing plate. The flexographic printing plate has an image area and a non-image area. The flexographic printing plate is not limited to those shown below.

Here, the above-described image area is an image area which is obtained by imagewise exposing and developing the photosensitive layer of the flexographic printing plate precursor.

From the reason that printing durability, handleability, and rear end ink receptivity are more excellent, the printing plate is preferably obtained by the following method.

In order to form the image area on the photosensitive layer of the flexographic printing plate precursor, first, irradiation with ultraviolet light is performed on the support side of the flexographic printing plate precursor (back exposure).

In a case of using the analog type printing plate precursor, the protective film is peeled off, and the negative film on which an image is formed in advance is closely attached to the exposed anti-adhesion layer. On the other hand, in a case of using the LAM type printing plate precursor, the protective film is peeled off, and a pattern showing a desired image is formed by, for example, irradiating the exposed infrared ablation layer with an infrared laser.

Next, the photosensitive layer is cured by irradiating ultraviolet light from above the negative film or the infrared ablation layer (main exposure). The main exposure corresponds to the above-described exposure step.

In the photosensitive layer, for example, the irradiated exposed portion is cured by the irradiation with ultraviolet light. The photosensitive layer covered with the negative film or the infrared ablation layer has an exposed portion irradiated with ultraviolet light and a non-exposed portion not irradiated with ultraviolet light. The exposed portion is a cured portion, and the non-exposed portion is an uncured portion.

Next, the non-exposed portion, that is, the uncured portion of the photosensitive layer is removed in a developer to leave the exposed portion of the photosensitive layer and obtain an image area and a non-image area.

A water-based developer (aqueous developer) is used as the developer. The aqueous developer is composed of water to which a surfactant, a pH adjuster, or the like is added as necessary. The uncured portion of the photosensitive layer can be removed by, for example, washing out the uncured portion using a spray type developing device or a brush-type washing machine.

Next, the printing plate material is taken out from the developer and dried. Next, the entire dried printing plate material is irradiated with ultraviolet light as necessary (post-exposure). As a result, a flexographic printing plate is obtained.

The present invention is basically configured as described above. The method for producing a flexographic printing plate according to the embodiment of the present invention has been described in detail above, but the present invention is not limited to the above-described embodiments, and various improvements and changes can be made without departing from the spirit of the present invention.

### EXAMPLES

Hereinafter, the characteristics of the present invention will be described in detail using examples. The materials, reagents, amounts and proportions of substances, operations, and the like described in the following examples can be appropriately modified as long as the gist of the present invention is maintained. Therefore, the scope of the present invention is not limited to Examples shown below.

In Examples, the depth of the concave portion and the reproduction of the independent dots were evaluated for Examples 1 to 6 and Comparative Examples 1 and 2 below. Table 1 below shows the evaluation results of the depth of the concave portion and the reproduction of the independent dots. Hereinafter, the depth of the concave portion and the reproduction of the independent dots will be described.

[Depth of Concave Portion]

The depth of the concave portion of the obtained flexographic printing plate was evaluated by the following method. Using a hybrid laser microscope OPTELICS (registered trademark) HYBRIDE (manufactured by Lasertec Corporation), a confocal measurement was performed on a surface of the solid image area of the flexographic printing plate with a 50% halftone dot portion in increments of 0.1 μm in height with a 50× Apo objective lens (high numerical aperture (high NA)) to obtain three-dimensional data. The depth of the concave portion between centers of dots was measured from the above-described observation image. The measured depth of the concave portion was evaluated based on the following evaluation standard.

(Evaluation Standard)
A: depth of the concave portion was 60 μm or more.
B: depth of the concave portion was 50 μm or more and less than 60 μm.
C: depth of the concave portion was less than 50 μm

[Reproduction of Independent Dots]

The reproduction of the independent dots of the obtained flexographic printing plate was evaluated by the following method. The flexographic printing plate was observed with a loupe, and reproduction of each independent dot of 50 μm-dots and 100 μm-dots was confirmed. From the observed independent dots, the reproduction of the independent dots was evaluated based on the following evaluation standard.

(Evaluation Standard)
A: 100 μm-dots and 50 μm-dots were reproduced.
B: 100 μm-dots were reproduced and 50 μm-dots were not reproduced.
D: 100 μm-dots and 50 μm-dots were not reproduced.

Next, Examples 1 to 6 and Comparative Examples 1 and 2 will be described. Examples 1 to 6 and Comparative Examples 1 and 2 are also shown in Table 1.

### Example 1

[Manufacturing of Flexographic Printing Plate]

(Back Exposure Step)

As a flexographic printing plate precursor, FLENEX FW-L2 (thickness: 1.14 mm) manufactured by FUJIFILM Graphic Solutions Corporation was used.

The flexographic printing plate precursor was exposed (back-exposed) with an exposure amount of 256 mJ/cm² from a distance of 15 cm from a support side of the flexographic printing plate precursor, using an exposure device in which 15 40 W chemical lamps were arranged.

(Negative Pattern Forming Step)

After performing the back exposure, a protective film of the flexographic printing plate precursor was peeled off, and a negative pattern was formed on an infrared ablation layer using an exposure device. The negative pattern includes a pattern corresponding to a 50% halftone dot portion, a solid image area, a 100 μm-dot, and a 50 μm-dot.

As the exposure device, an exposure device in which 15 40 W chemical lamps were arranged was used. The exposure device irradiated ultraviolet light as energy ray, and the ultraviolet light was in a state of scattered light.

(Main Exposure Step)

Two film-like optical elements 1 were arranged on the flexographic printing plate precursor on which the negative pattern had been formed, in which an uneven surface was disposed on the flexographic printing plate precursor side. The film-like optical element 1 was a prism sheet. The two film-like optical elements 1 were arranged between the above-described exposure device used as an energy source and the flexographic printing plate precursor, such that the prism sheets were laminated to that extending directions of the prisms were orthogonal to each other, and the surface on which the prisms of each prism sheet were arranged was on the side opposite to the light incident side.

The flexographic printing plate precursor was exposed (main-exposed) with an exposure amount of 2880 mJ/cm² from a distance of 15 cm from the infrared ablation layer side through the two film-like optical elements 1, using the above-described exposure device as the energy source.

(Development Step)

After performing the main exposure, development was performed for 10 minutes using a brush-type washing machine (liquid temperature: 50° C.) containing an aqueous developer in which the concentration of detergent (manufactured by MIYOSHI SOAP CORPORATION, additive-free dishwashing soap) was adjusted to 0.5%. Thereafter, the obtained product was dried with hot air of 60° C. until the moisture was removed.

(Post-Exposure Step)

After the drying, without disposing the film-like optical element 1, exposure (post-exposure) was performed with an exposure amount of 2000 mJ/cm² from a distance of 15 cm from the photosensitive layer side, using the above-described exposure device. In this way, a flexographic printing plate was obtained.

[Film-Like Optical Element 1]

As the film-like optical element 1, LPV90-0.1 (grade without UV absorber; prism plate having a pitch of 0.1 mm, prism angle: 90 degrees) manufactured by Nihon Tokushu Kogaku Jushi Co., Ltd. was used. As described above, the film-like optical element 1 was a prism sheet and was manufactured by melt molding.

### Example 2

In Example 2, a flexographic printing plate was manufactured in the same manner as in Example 1, except that a film-like optical element 2 was used.

[Film-Like Optical Element 2]

As the film-like optical element 2, LL0.1-0.05 (grade without UV absorber; linear lenticular lens having a pitch of 0.1 mm, cylindrical lens radius: 0.05 mm) manufactured by Nihon Tokushu Kogaku Jushi Co., Ltd. was used. The film-like optical element 2 was manufactured by melt molding.

### Example 3

In Example 3, a flexographic printing plate was manufactured in the same manner as in Example 1, except that a film-like optical element 3 was used.

[Film-Like Optical Element 3]

As the film-like optical element 3, a quartz glass prism sheet which was produced by mold pressing using a mold with a pitch of 0.1 mm, a prism angle of 90 degrees, and a total thickness of 2 mm was used.

### Example 4

In Example 4, a flexographic printing plate was manufactured in the same manner as in Example 1, except that a film-like optical element 4 was used.

[Film-Like Optical Element 4]

As the film-like optical element 4, 199 parts by mass of methyl methacrylate manufactured by Tokyo Chemical Industry Co., Ltd. and 1 part by mass of benzoyl peroxide manufactured by Tokyo Chemical Industry Co., Ltd. were mixed, reacted at a temperature of 90° C. with stirring until a viscosity of 0.1 pascal second (1 poise) was reached, and quenched with dry ice and methanol. The obtained liquid was poured into the same mold as in the film-like optical element 3 of Example 3 described above, and heated at a temperature of 90° C. for 20 hours and at a temperature of 110° C. for 2 hours to obtain a prism sheet used as the film-like optical element. The film-like optical element 4 was formed by thermal polymerization.

### Example 5

In Example 5, a flexographic printing plate was manufactured in the same manner as in Example 1, except that a film-like optical element 5 was used.

[Film-Like Optical Element 5]

As the film-like optical element 5, a mixture obtained by adding 1-hydroxycyclohexylphenylketone of Tokyo Chemical Industry Co., Ltd. to 356.25 parts by mass of A-NOD-N(1,9-nonanediol diacrylate) of Shin-Nakamura Chemical Co., Ltd. and stirring was poured into the same mold as in the film-like optical element 3 of Example 3 described above, and covered with a glass plate. Using a metal halide lamp UVL-1500M2 manufactured by USHIO INC., ultraviolet curing was performed by radiating ultraviolet rays with a condition of 450 mJ/cm² from the glass plate side to obtain a prism sheet used as the film-like optical element. The film-like optical element 5 was formed by ultra-short wave UV polymerization.

### Example 6

In Example 6, a flexographic printing plate was manufactured in the same manner as in Example 1, except that, using, as the energy source, an LED area exposure device (UVA 500×500) manufactured by Microsquare, Inc., the flexographic printing plate precursor was exposed with an exposure amount of 2880 mJ/cm² from a distance of 5 cm from the infrared ablation layer side through the two film-like optical elements 1. Same as Example 1, the two film-like optical elements 1 were arranged between the above-described LED area exposure device used as an energy source and the flexographic printing plate precursor, such that the prism sheets were laminated to that extending directions of the prisms were orthogonal to each other, and the surface on which the prisms of each prism sheet were arranged was on the side opposite to the light incident side.

### Comparative Example 1

In Comparative Example 1, a flexographic printing plate was manufactured in the same manner as in Example 1, except that the film-like optical element was not used. In Comparative Example 1, the exposure was performed using scattered light.

In Comparative Example 1, since the film-like optical element was not used, the columns of name, material, shape, and manufacturing method of the film-like optical element in Table 1 were indicated by “-”.

### Comparative Example 2

In Comparative Example 1, a flexographic printing plate was manufactured in the same manner as in Example 1, except that the film-like optical element was not used, and as the exposure device, UVE-365-4040 manufactured by Kantum Ushikata Co., LTD. was used. In Comparative Example 2, the exposure was performed using fully collimated light.

In Comparative Example 2, since the film-like optical element was not used, the columns of name, material, shape, and manufacturing method of the film-like optical element in Table 1 were indicated by “-”.

TABLE 1

| | | | | | | | Evaluation | |
|---|---|---|---|---|---|---|---|---|
| | | Exposure | Film-like optical element | | | | Depth of | Reproduction |
| | Exposure | light | | | | Manufacturing | concave | of independent |
| | light | source | Name | Material | Shape | method | portion | dots |
| Example 1 | Scattered | Fluorescent | Film-like | Resin | Prism | Melt molding | A | A |
| | light | lamp | optical | | | | | |
| | | | element 1 | | | | | |
| Example 2 | Scattered | Fluorescent | Film-like | Resin | Lenticular | Melt molding | A | A |
| | light | lamp | optical | | lens | | | |
| | | | element 2 | | | | | |
| Example 3 | Scattered | Fluorescent | Film-like | Glass | Prism | Mold pressing | A | A |
| | light | lamp | optical | | | | | |
| | | | element 3 | | | | | |
| Example 4 | Scattered | Fluorescent | Film-like | Resin | Prism | Thermal | A | A |
| | light | lamp | optical | | | polymerization | | |
| | | | element 4 | | | | | |
| Example 5 | Scattered | Fluorescent | Film-like | Resin | Prism | Ultra-short | B | B |
| | light | lamp | optical | | | wave UV | | |
| | | | element 5 | | | polymerization | | |
| Example 6 | Scattered | LED | Film-like | Resin | Prism | Melt molding | A | A |
| | light | | optical | | | | | |
| | | | element 1 | | | | | |

| | | | | | | |
|---|---|---|---|---|---|---|
| Comparative | Scattered | Fluorescent | — | — | C | A |
| Example 1 | light | lamp | | | | |
| Comparative | Fully | LED | — | — | A | C |
| Example 2 | collimated | | | | | |
| | light | | | | | |

As shown in Table 1, in Examples 1 to 6, compared with Comparative Examples 1 and 2, both the depth of the concave portion and the reproduction of the independent dots could be achieved.

In Comparative Example 1, since the film-like optical element was not used, the depth of the concave portion was insufficient due to halation with the scattered light.

In Comparative Example 2, since the film-like optical element was not used, the reproduction of the independent dots was poor due to the fully collimated light.

From Examples 1 to 6, in Examples 1 to 4, and 6, the transmission of the exposure light by the film-like optical elements 1 to 4 was sufficient, and the depth of the concave portion and the reproduction of the independent dots were excellent.

### EXPLANATION OF REFERENCES

10, 10a, 10b: flexographic printing plate precursor
12: energy source
14: film-like optical element
20: support
21: adhesive layer
22: photosensitive layer
22a, 32a: surface
23a: exposed portion
23b: non-exposed portion
24: mask portion
laminate
32: infrared ablation layer
33: opening
34: adhesive layer
35: carrier sheet
35a: surface
37: protective sheet
Le: energy ray

What is claimed is:

1. A manufacturing method of a flexographic printing plate, comprising:
an exposure step of irradiating, with an energy ray, a flexographic printing plate precursor which includes, in the following order, at least a support, a photosensitive layer, and a mask portion on which an image is formed, through the mask portion to expose the photosensitive layer; and
a development step of removing a non-exposed portion of the photosensitive layer,
wherein the exposure step includes a step of radiating the energy ray in a state in which, from the photosensitive layer side, the mask portion and a film-like optical element are present in this order between an energy source and the photosensitive layer, and
the film-like optical element is an element which converges the incident energy ray to enhance directivity and emits the energy ray to the mask portion.

2. The manufacturing method of a flexographic printing plate according to claim 1,
wherein the energy ray is ultraviolet light.

3. The manufacturing method of a flexographic printing plate according to claim 1,
wherein the film-like optical element is a prism sheet or a lenticular lens.

4. The manufacturing method of a flexographic printing plate according to claim 1,
wherein the film-like optical element is formed from glass.

5. The manufacturing method of a flexographic printing plate according to claim 1,
wherein the film-like optical element is formed from a resin.

6. The manufacturing method of a flexographic printing plate according to claim 2,
wherein the film-like optical element is a prism sheet or a lenticular lens.

7. The manufacturing method of a flexographic printing plate according to claim 2,
wherein the film-like optical element is formed from glass.

8. The manufacturing method of a flexographic printing plate according to claim 2,
wherein the film-like optical element is formed from a resin.

9. The manufacturing method of a flexographic printing plate according to claim 3,
wherein the film-like optical element is formed from glass.

10. The manufacturing method of a flexographic printing plate according to claim 3,
wherein the film-like optical element is formed from a resin.
